(19) United States
(12) Patent Application Publication
(10) Pub. No.: US 2014/0056031 A1
(43) Pub. Date: Feb. 27, 2014

(54) BEND-RESISTANT BOTTOM CHASSIS AND DISPLAY DEVICE HAVING THE SAME

(71) Applicant: SAMSUNG DISPLAY CO., LTD., Yongin-City (KR)

(72) Inventors: Sanghwan LEE, Asan-si (KR); Sungjin WOO, Seoul (KR)

(73) Assignee: SAMSUNG DISPLAY CO., LTD., Yongin-City (KR)

(21) Appl. No.: 13/793,857

(22) Filed: Mar. 11, 2013

(30) Foreign Application Priority Data
Aug. 23, 2012 (KR) 10-2012-0092463

(51) Int. Cl. F21V 8/00; H05K 5/00

(52) U.S. Cl. CPC G02B 6/0093; H05K 5/0017
USPC 362/633; 312/7.2

(57) ABSTRACT

A display device is provided which includes a backlight unit including a light guide plate and a light source unit for supplying light to the light guide plate, the light guide plate configured to guide light from the light source unit; a display panel configured to display images using the light provided from the backlight unit; and a bottom chassis configured to receive the backlight unit and the display panel. The bottom chassis comprises a bottom portion on which the backlight unit and the display panel are placed; a plurality of lateral walls extending from the bottom portion toward the display panel; and at least one flange extending from at least one of the lateral walls, the bottom portion including a stress releasing member configured to prevent a stress induced in the flange from being transferred to the display panel.

### CROSS-REFERENCE TO RELATED APPLICATIONS

This U.S. non-provisional patent application claims priority under 35 U.S.C. §119 to Korean Patent Application No. 10-2012-0092463, filed Aug. 23, 2012 in the Korean

Intellectual Property Office, the content of which is hereby incorporated by reference herein in its entirety.

### BACKGROUND

The inventive concepts described herein relate generally to a flat panel display device, and more particularly relate to a display device that is more resistant to bending, as well as a bottom chassis for the display device.

Flat panel display devices such as liquid crystal display devices, electrophoretic display devices, electro-wetting display devices, and organic light-emitting display devices may be light, thin, and low-power. Such characteristics may enable these flat display devices to be widely used in a variety of fields of application. In particular, flat panel display devices have found applications in portable data processing devices such as cellular phones, tablets, notebooks, and so on.

In a flat panel display device, a display panel for displaying images may be received and fixed by a separate reception container called a bottom chassis. This bottom chassis may be fixed to a case of the data processing device through a flange disposed at one side.

If external pressure is applied to the flange, the flange may rotate due to a torque generated by the external pressure. The torque may be transferred to another portion of the bottom chassis by bending of the bottom chassis. In this case, a part of the bottom chassis may be pressed by the flat panel display device. The flat panel display device may be distorted or broken according to a level of the pressure.

### SUMMARY

Example embodiments of the inventive concept provide a display device comprising a backlight unit including a light guide plate and a light source unit configured to supply light to the light guide plate, the light guide plate configured to guide light from the light source unit; a display panel configured to display images using the light provided from the backlight unit; and a bottom chassis configured to receive the backlight unit and the display panel. The bottom chassis comprises a bottom portion on which the backlight unit and the display panel are placed; a plurality of lateral walls extending from the bottom portion toward the display panel; and at least one flange extending from at least one of the lateral walls, the bottom portion including a stress releasing member configured to prevent a stress induced in the flange from being transferred to the display panel.

In example embodiments, the bottom portion includes a first area adjacent to the lateral walls and extending from the display panel, and a second area at least partially enclosed by the first area.

In example embodiments, the second area is an open area.

In example embodiments, the stress releasing member includes a stress releasing area that is an opening in the first area.

In example embodiments, a width of the stress releasing area is greater than a width of the flange.

In example embodiments, the stress releasing member further comprises a cover portion covering the stress releasing area.

In example embodiments, the cover portion is connected to the first area at a corner of the stress releasing area.

In example embodiments, the stress releasing member is disposed in the bottom portion under the display panel.

In example embodiments, the bottom chassis has an elasticity.

Example embodiments of the inventive concept also provide a display device comprising a backlight unit including a light guide plate and a light source unit configured to supply light to the light guide plate, the light guide plate configured to guide light from the light source unit; a display panel configured to display images using the light provided from the backlight unit; and a bottom chassis configured to receive the backlight unit and the display panel. The bottom chassis comprises a bottom portion on which the backlight unit and the display panel are placed; a plurality of lateral walls extending from the bottom portion toward the display panel; at least one flange connected to at least one of the lateral walls; and a stress releasing member disposed between the flange and the at least one lateral wall. The stress releasing member can be configured to prevent a stress induced in the flange from being transferred to the at least one lateral wall.

In example embodiments, the stress releasing member comprises a first bent portion extending from a top of the at least one lateral wall and bent in a direction opposite to a direction in which the at least one lateral wall is bent; and a second bent portion extending from the first bent portion and bent in a direction opposite to a direction in which the first bent portion is bent, the second bent portion being connected with the flange.

In example embodiments, the bottom chassis has an elasticity.

Example embodiments of the inventive concept also provide a bottom chassis of a display device, comprising a bottom portion on which a backlight unit and a display panel can be placed; a plurality of lateral walls extending from the bottom portion; at least one flange connected to at least one of the lateral walls; and a stress releasing member configured to prevent a stress induced in the flange from being transferred to the display panel.

In example embodiments, the bottom portion includes a first area adjacent to the lateral walls and extending from the display panel, and a second area at least partially enclosed by the first area.

In example embodiments, the stress releasing member comprises a stress releasing area comprising an opening in the first area; and a cover portion covering the stress releasing area.

In example embodiments, a width of the stress releasing area is greater than a width of the flange.

In example embodiments, the cover portion is connected to the first area at a corner of the stress releasing area.

In example embodiments, the stress releasing member is disposed between the flange and the at least one lateral wall.

In example embodiments, the stress releasing member comprises a first bent portion extending from a top of the at least one lateral wall and bent in a direction opposite to a direction in which the at least one lateral wall is bent; and a second bent portion extending from the first bent portion and bent in a direction opposite to a direction in which the first bent portion is bent, the second bent portion being connected with the flange.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a perspective exploded view for describing a display device according to an embodiment of the inventive concept;

FIG. 2 is a view illustrating a cross section taken along a line I-I′ in FIG. 1;

FIG. 3 is a top view of a bottom chassis illustrated in FIG. 1;

FIG. 4 is a view illustrating a cross section taken along a line II-II′ in FIG. 3;

FIG. 5 is a diagram for describing how a stress of a bottom chassis is released;

FIG. 6 is a cross-sectional view for describing how external pressure transferred to a flange from a general bottom chassis not including a stress releasing member is transferred to a display panel and a backlight unit;

FIG. 7 is a top view for describing a bottom chassis applied to a display device according to another embodiment of the inventive concept;

FIG. 8 is a view illustrating a cross section taken along a line III-III′ in FIG. 7; and

FIG. 9 is a diagram for describing how a stress of a bottom chassis is released.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

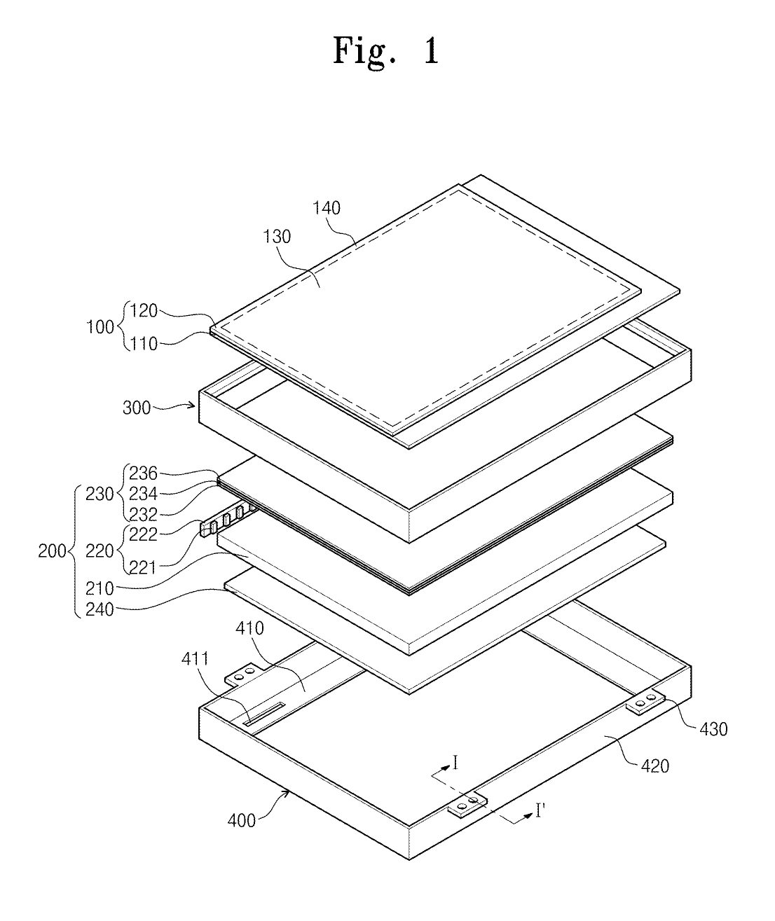

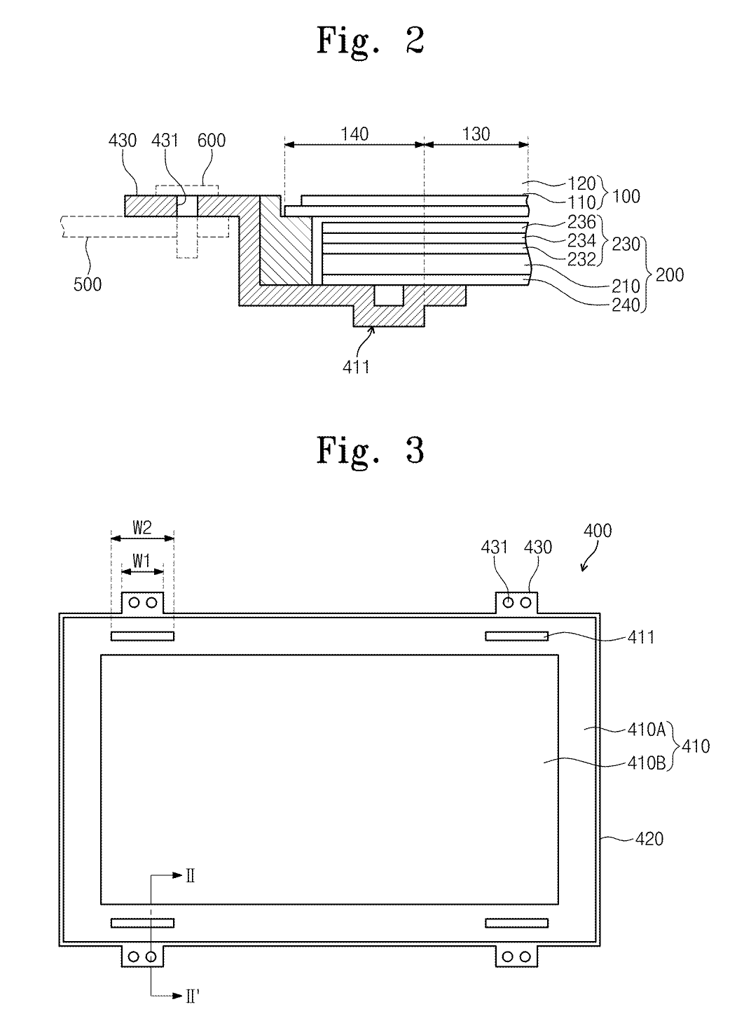

FIG. 1 is a perspective exploded view for describing a display device according to an embodiment of the inventive concept. FIG. 2 is a view illustrating a cross section taken along a line I-I′ in FIG. 1.

Referring to FIGS. 1 and 2, a display device according to an embodiment of the inventive concept may include a display panel 100 for displaying images, a backlight unit 200 for supplying light to the display panel 100, a mold frame 300, and a bottom chassis 400.

The display panel 100 may have a display area for displaying an image, and the display area may display an image using light. The display panel may be formed of a liquid crystal display panel, an electrophoretic display panel, or the like. In this embodiment, the display panel may be a liquid crystal display panel.

The display panel 100 may have a generally rectangular plate shape having a long edge and a short edge, and may be divided into a display area 130 for displaying images and a non-display area 140 surrounding the display area 140. The display panel 100 may include an array substrate 110, an opposite substrate 120 opposed to the array substrate 110, and a liquid crystal layer (not shown) formed between the array substrate 110 and the opposite substrate 120.

With an embodiment of the inventive concept, although not shown, the array substrate 110 may include a plurality of gate lines extending along a first direction and a plurality of data lines extending along a second direction approximately perpendicular to the first direction so as to intersect, yet remain electrically insulated from, the gate lines. The array substrate 110 may further include a plurality of pixels arranged in a matrix form (not shown). Each pixel may include a thin film transistor and a pixel electrode, each also not shown. Herein, a gate electrode of a thin film transistor may be electrically connected to a corresponding one of the gate lines, a source electrode thereof may be connected to a corresponding one of the data lines, and a drain electrode thereof may be electrically connected to the pixel electrode. Thus, the thin film transistor may switch a pixel controlling or driving signal to the pixel electrode.

Although not shown, the opposite substrate 120 may include an RGB color filter which is provided on one surface of the opposite substrate 120 and realizes a color using a light, and a common electrode which is formed on the RGB color filter and is opposite to the pixel electrode. Herein, the RGB color filter may be formed using a thin film process. There is described an example in which a color filter is formed on the opposite substrate 120. However, the inventive concept is not limited thereto. For example, the color filter can be formed on the array substrate 110.

The liquid crystal layer may be arranged in a specific direction by voltages applied to the pixel electrode and the common electrode to adjust the transmittance of light from the backlight unit 200. In this manner, an image may be displayed by the display panel 100.

Meanwhile, polarization films (not shown) may be attached to one or both surfaces of the display panel 100, that is, external surfaces of the array substrate 110 and the opposite substrate 120, respectively.

The backlight unit 200 may be disposed to be opposed to one surface of the display panel 100, for example, a surface opposite to an external (hereinafter, referred to as ‘bottom’) direction of the array substrate 110, and may supply light to the display panel 100. Light supplied to the display panel 100 may be output from the other surface of the display panel 100, that is, an external (hereinafter, referred to as ‘top’) direction of the opposite substrate 120, so as to display an image. Herein, the backlight unit 200 may include a light guide unit 210 guiding light, a light source unit 220 supplying light to the light guide unit 210, an optical member 230, and a refraction sheet 240.

The light guide plate 210 may have a rectangular plate shape corresponding to a shape of the display panel 100. The light guide plate 210 may be formed of a transparent material capable of refracting light. For example, the light guide plate 210 may be formed of transparent polymer resin such as polycarbonate, polymethyl methacrylate, or the like. The light guide plate 210 may be disposed at a bottom of (i.e., beneath) the display panel 100, and may guide light emitted from the light source unit 220 to be output in a display panel 100 direction (i.e., through the display panel 100). The light guide plate 210 may be overlapped at least with the display area of the display panel 100. The light guide plate 210 may have a top surface, a bottom surface opposite to the top surface, and a plurality of lateral walls connecting the top surface and the bottom surface. At least one of the lateral walls may be an incident surface on which light emitted from the light source unit 220 is incident. The top surface may be an output surface facing the display panel 100, and which guides the light such that light is output toward the display panel 100.

The light source unit 220 may include at least one light source 221 and a printed circuit board 222 applying power to the light source 221. The light source 221 may be mounted on one surface of the printed circuit board 222. The light source 221 may include a Light Emitting Diode (LED), for example. A radiation member (not shown) for dissipating heat generated by the light source 221 may be disposed on a surface of the printed circuit board 222 opposite to a surface on which the light source 221 is mounted. The light source unit 220 may be disposed to be opposed to one lateral wall of the light guide plate 210, and may supply light to the light guide plate 210.

The optical member 230 may be provided between the light guide plate 210 and the display panel 100. The optical member 230 may perform the role of controlling light which is provided from the light source unit 220 and which is output through the light guide plate 210. Also, the optical member 230 may include a diffusion sheet 232, a prism sheet 234, and a protection sheet 236 which are sequentially stacked.

The diffusion sheet 232 may perform the role of diffusing light output from the light guide plate 210. The prism sheet 234 may concentrate light diffused from the diffusion sheet 232 in a direction perpendicular to a flat surface of the display panel 100. Light passing through the prism sheet 234 may be incident mainly on the display panel 100. The protection sheet 236 may be placed on the prism sheet 234. The protection sheet 236 may protect the prism sheet 234 from external impact.

In example embodiments, there is illustrated the optical member 230 formed of a diffusion sheet, a prism sheet, and a protection sheet. However, the inventive concept is not limited thereto. For example, in the optical member 230, at least one of the diffusion sheet 232, the prism sheet 234, and the protection sheet 236 can be formed of a plurality of overlapping sheets. If desired, at least one of the diffusion sheet 232, the prism sheet 234, and the protection sheet 236 can be skipped.

A reflection sheet 240 may be disposed at a bottom of the light guide plate 210. The reflection sheet 240 may reflect leaked light back toward the display panel 100. The reflection sheet 240 may include a material that reflects light. The reflection sheet 240 may be provided on the bottom chassis 400, and may reflect light output from the light source unit 220. The reflection sheet 240 may increase the amount of light being provided to the display panel 100.

The mold frame 300 may have a square ring shape (i.e. a square or rectangular frame with flanges extending inward from one or more sides) such that the display panel 100 and the backlight unit 200 are received and supported by the square ring shape. As illustrated in the figures, the mold frame 300 may be single. Alternatively, a plurality of mold frames can be provided.

The bottom chassis 400 may be disposed at a bottom of the backlight unit 200 to receive the display panel 100, the backlight unit 200, and the mold frame 300. The bottom chassis 400 may be formed of an elastic material. That is, the bottom chassis may have an elasticity. Also, the bottom chassis 400 may include a bottom portion 410 corresponding to shapes of the display panel 100 and the backlight unit 200, a plurality of lateral walls 420 extended from the bottom portion 410 and bent (or otherwise oriented) upward, and at least one flange 430 extended from at least one of the lateral walls 420 and bent to be at least approximately parallel with the bottom portion 410. In the bottom chassis 400, the bottom portion 410 and the lateral walls 420 may form a space in which the display panel 100, the backlight unit 200, and the mold frame 300 are received.

The bottom portion 410 may include a stress releasing member 411 for releasing a stress caused when external pressure is applied to the flange 430. The stress releasing member 411 may be disposed at the bottom portion 410 corresponding to the display panel 100.

The flange 430 may include a connection member 600 and at least one connection hole 431 formed to be coupled with a connection member 600 such as a screw. The connection member 600 may enable the bottom chassis 400 to be fixed through connection with the case 500 of a data processing device.

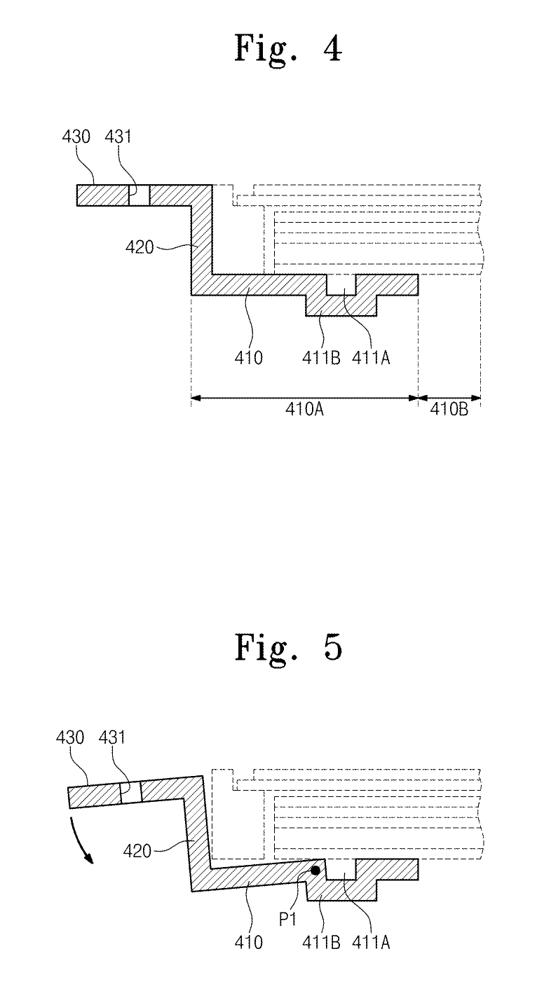

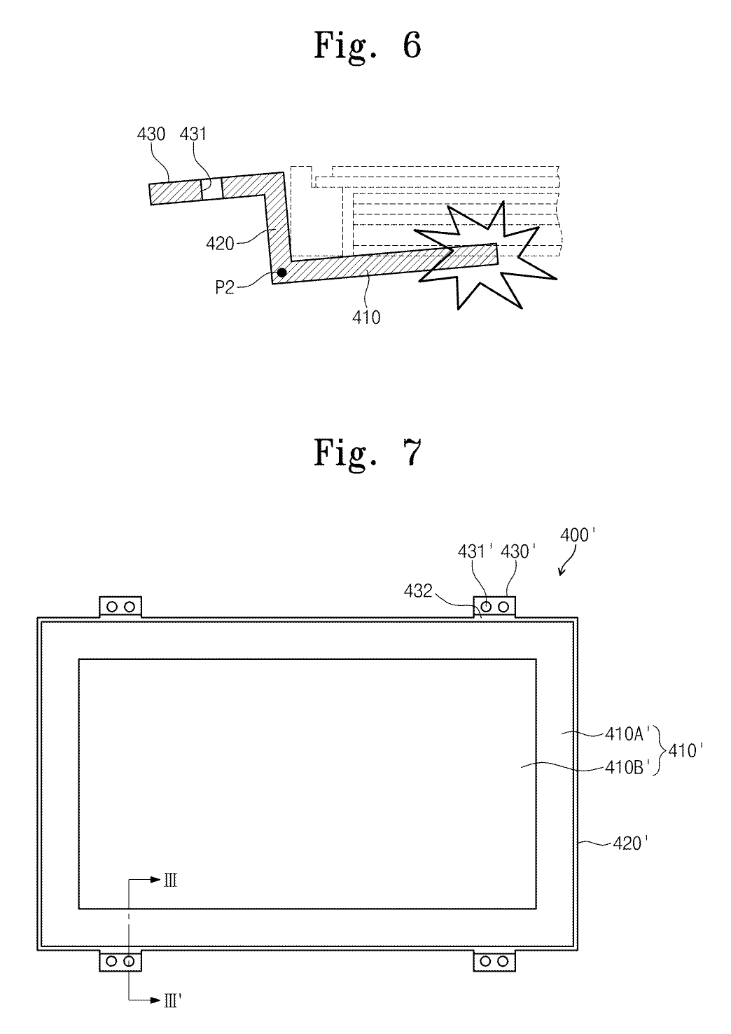

FIG. 3 is a top view of a bottom chassis illustrated in FIG. 1. FIG. 4 is a view illustrating a cross section taken along a line II-II′ in FIG. 3. FIG. 5 is a diagram for describing how a stress of a bottom chassis is released. FIG. 6 is a cross-sectional view for describing how external pressure transferred to a flange from a general bottom chassis not including a stress releasing member is transferred to a display panel and a backlight unit.

The effect of external pressure applied to a flange 430 according to whether a stress releasing member 411 exists or not will be described with reference to FIGS. 5 and 6.

Referring to FIGS. 3 to 6, a bottom chassis 400 may receive a display panel 100, a backlight unit 200, and a mold frame 300. The bottom chassis 400 may include a bottom portion 410, a plurality of lateral walls 420 extended from the bottom portion 410 and bent upward, and at least one flange 430 extended from at least one of the lateral walls 420 and bent to be parallel with the bottom portion 410. In the bottom chassis 400, the bottom portion 410 and the lateral walls 420 may form a space in which the display panel 100, the backlight unit 200, and the mold frame 300 are received.

The bottom portion 410 may include a first area 410A adjacent to the lateral walls 420 and supporting the display panel 100, and a second area 410B corresponding to the remaining area surrounded by the first area 410A. Herein, the second area 410B may be an open area, i.e. the open area that lies within the inner edges of the first area 410A.

A stress releasing member 411 may be disposed at the first area 410A. The stress releasing member 411 may include a stress releasing area 411A having an opened shape (i.e., that is an opening in the stress relieving member 411) formed by removing a part of the first area 410A, and a cover portion 411B for covering the stress releasing area 411A in a direction opposite to a direction in which the lateral walls 420 are bent (i.e., a cover positioned on the opposite side of the bottom chassis 400 from the walls 420).

The stress releasing area 411A may prevent external pressure applied to the flange 430 from being transferred to the bottom portion 410. That is, the stress releasing area 411A may prevent the external pressure from being transferred to various sheets of the backlight unit 200 and the display panel 100. In example embodiments, the stress releasing area 411A may have a square or rectangular shape.

A width W2 of the stress releasing area 411A may be wider than a width W1 of the flange 430. In the case that the width W2 of the stress releasing area 411A is narrower than the width W1 of the flange 430, a stress transferred from the flange 430 may not be sufficiently released, so that the stress is transferred to the backlight unit 200 and the display panel 100 through the first area 410A.

The cover portion 411B may be connected with the first area 410A at a corner of the stress releasing area 411A, and may support the first area 410A around the stress releasing area 411A. Thus, the cover portion 411B may prevent cracks in the first area 410A generated by the stress concentrations at the corners of the stress releasing area 411A.

The flange 430 may include a connection member 600 and at least one connection hole 431 formed to be connected with the connection member 600, such as a screw. The connection member 600 may enable the bottom chassis 400 to be fixed via connection with the case 500 of a data processing device. Although not shown in the figures, in the case that the connection member 600 is a screw, a screw thread may be formed at an inner surface of the connection hole 431.

Below, the effect of a bottom chassis having the stress releasing member 411 will be described with reference to FIG. 5. For ease of description, the effect of the bottom chassis having the stress releasing member 411 will be described together with reference to FIG. 6.

As illustrated in FIG. 5, if external pressure is applied to the flange 430, torque may be generated at the flange 430 in the direction of the arrow. The flange 430, the lateral wall 420, and a region of the first area 410A between the lateral wall 420 and the stress releasing member 411 may be deformed in the downward direction by the torque. Herein, a supporting point P1 of the torque may be a point, adjacent to the lateral wall 420, from among points at which the bottom portion 410 and the cover portion 411B are connected.

The torque applied to the flange 430 may impart a rotary motion to the flange 430, the lateral wall 420, and an area of the first area 410A between the lateral wall 420 and the stress releasing member 411. This may mean that the torque is not transferred from the first area 410A to an area between the second area 410B and the stress releasing member 411. Thus, stresses resulting from the external pressure applied to the flange 430 may not be transferred to the backlight unit 200 and the display panel 100. That is, stresses induced in the flange 430 are relieved by the stress releasing member 411 rather than being transferred to the lateral wall 420.

The bottom chassis 400 may be formed of an elastic material. Thus, if the external pressure applied to the flange 430 is removed, the flange 430, the lateral wall 420, and an area of the first area 410A between the lateral wall 420 and the stress releasing member 411 may return to its original position and shape.

Meanwhile, as illustrated in FIG. 6, in the case that the bottom portion 410 does not include the stress releasing member 411, the flange 430, the lateral wall 420, and the bottom portion 410 may be deformed by the torque. In this case, a point at which the lateral wall 420 and the bottom portion 410 are connected to each other may act as a supporting point P2 of the torque. Thus, an end of the first area 410A of the bottom portion 410 may be pushed upward toward the backlight unit 200. The resulting pressure and stresses may deform or break the backlight unit 200 and/or the display panel 100.

As described above, although external pressure is applied to the flange 430, the bottom chassis 400 may substantially prevent the resulting stresses from being transferred to the backlight unit 200 and the display panel 100. Thus, a display device including the bottom chassis 400 may prevent the backlight unit 200 and the display panel 100 from being bent or broken when external pressure is applied to the display device.

Below, another embodiment of the inventive concept will be described with reference to FIGS. 7 to 9. In FIGS. 7 to 9, a detailed description of components illustrated in

FIGS. 1 to 6 will be largely omitted. Also, a difference between an embodiment in FIGS. 7 to 9 and an embodiment in FIGS. 1 to 6 will be mainly described.

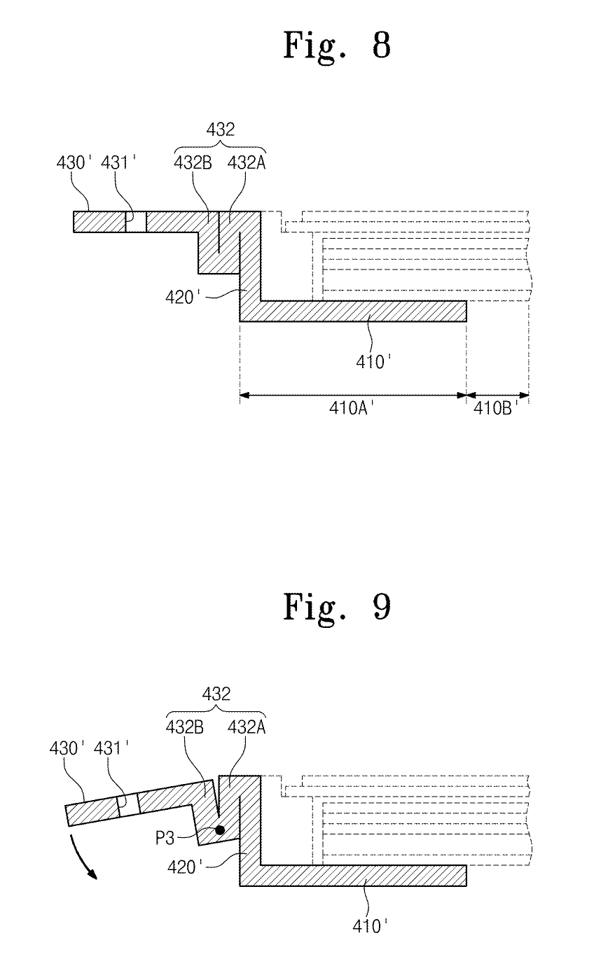

FIG. 7 is a top view for describing a bottom chassis applied to a display device according to another embodiment of the inventive concept. FIG. 8 is a view illustrating a cross section taken along a line III-III′ in FIG. 7. FIG. 9 is a diagram for describing how a stress of a bottom chassis is released.

Referring to FIGS. 7 to 9, a bottom chassis 400′ may include a bottom portion 410′, a plurality of lateral walls 420′ extended from the bottom portion 410′ and bent upward, at least one flange 430′ connected to at least one of the lateral walls 420′, and a stress releasing member 432 disposed between the flange 430′ and the lateral wall 420′. The bottom portion 410′ and the lateral walls 420′ may form a space in which a display panel, a backlight unit, and a mold frame are received.

The bottom portion 410′ may include a first area 410A′ adjacent to the lateral walls 420′ and supporting the display panel, and a second area 410B′ corresponding to the remaining area within the first area 410A′. Herein, the second area 410B′ may be an open area.

The flange 430 may be extended in a direction parallel with the bottom portion 410′. At least one connection hole 431′ may be formed in the flange 430. A connection member may be inserted through the connection hole 431′, which enables the bottom chassis 400′ to be fixed through connection with a part of a case of a data processing device.

The stress releasing member 432 may include a first bent portion 432A and a second bent portion 432B. The first bent portion 432A may be extended from a top of the lateral wall 420′ so as to be bent in a direction opposite to a direction in which the lateral wall 420′ is bent. The second bent portion 432B may be extended from the first bent portion 432A so as to be bent in a direction opposite to a direction in which the first bent portion 432A is bent. Herein, one end of the second bent portion 432B may be connected with the flange 430′. The bent portions 432A and 432B are connected to each other to form a generally “U” shaped (when viewed in cross section), bent portion of the flange 430.

Below, how a stress caused by external pressure applied to the flange 430′ is not transferred to a backlight unit and a display panel, due to action of the stress releasing member 432, will be described.

If external pressure is applied to the flange 430′, torque generated by the external pressure may act upon the flange 430′. The flange 430′ and the second bent portion 432B may be deformed downward by the torque. Herein, a supporting point P3 of the torque may be a connection point of the first and second bent portions 432A and 432B.

The torque applied to the flange 430′ may deform the flange 430′ and the second bent portion 432B, but not the first bent portion 432A. This may mean that the torque is not transferred to the second bent portion 432A, the lateral walls 420′, and the bottom portion 410′. Thus, stresses from the external pressure applied to the flange 430′ may not be transferred to the backlight unit 200 and the display panel 100 by the stress releasing member 432.

The bottom chassis 400′ may be formed of an elastic material. Thus, if the external pressure forced to the flange 430′ is removed, the flange 430 and the second bent portion 432B may return to their original positions and/or shapes.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A display device, comprising:
a backlight unit including a light guide plate and a light source unit configured to supply light to the light guide plate, the light guide plate configured to guide light from the light source unit;
a display panel configured to display images using the light provided from the backlight unit; and
a bottom chassis configured to receive the backlight unit and the display panel,
wherein the bottom chassis comprises:
a bottom portion on which the backlight unit and the display panel are placed;
a plurality of lateral walls extending from the bottom portion toward the display panel; and
at least one flange extending from at least one of the lateral walls, the bottom portion including a stress releasing member configured to prevent a stress induced in the flange from being transferred to the display panel.

2. The display device of claim 1, wherein the bottom portion includes a first area adjacent to the lateral walls and extending from the display panel, and a second area at least partially enclosed by the first area.

3. The display device of claim 2, wherein the second area is an open area.

4. The display device of claim 2, wherein the stress releasing member includes a stress releasing area that is an opening in the first area.

5. The display device of claim 4, wherein a width of the stress releasing area is greater than a width of the flange.

6. The display device of claim 4, wherein the stress releasing member further comprises:
a cover portion covering the stress releasing area.

7. The display device of claim 6, wherein the cover portion is connected to the first area at a corner of the stress releasing area.

8. The display device of claim 1, wherein the stress releasing member is disposed in the bottom portion under the display panel.

9. The display device of claim 1, wherein the bottom chassis has an elasticity.

10. A display device, comprising:
a backlight unit including a light guide plate and a light source unit configured to supply light to the light guide plate, the light guide plate configured to guide light from the light source unit;
a display panel configured to display images using the light provided from the backlight unit; and
a bottom chassis configured to receive the backlight unit and the display panel,
wherein the bottom chassis comprises:
a bottom portion on which the backlight unit and the display panel are placed;
a plurality of lateral walls extending from the bottom portion toward the display panel;
at least one flange connected to at least one of the lateral walls; and
a stress releasing member disposed between the flange and the at least one lateral wall, the stress releasing member configured to prevent a stress induced in the flange from being transferred to the at least one lateral wall.

11. The display device of claim 10, wherein the stress releasing member comprises:
a first bent portion extending from a top of the at least one lateral wall and bent in a direction opposite to a direction in which the at least one lateral wall is bent; and
a second bent portion extending from the first bent portion and bent in a direction opposite to a direction in which the first bent portion is bent, the second bent portion being connected with the flange.

12. The display device of claim 10, wherein the bottom chassis has an elasticity.

13. A bottom chassis of a display device, comprising:
a bottom portion on which a backlight unit and a display panel can be placed;
a plurality of lateral walls extending from the bottom portion;
at least one flange connected to at least one of the lateral walls; and
a stress releasing member configured to prevent a stress induced in the flange from being transferred to the display panel.

14. The bottom chassis of claim 13, wherein the bottom portion includes a first area adjacent to the lateral walls and extending from the display panel, and a second area at least partially enclosed by the first area.

15. The bottom chassis of claim 14, wherein the stress releasing member comprises:
a stress releasing area comprising an opening in the first area; and
a cover portion covering the stress releasing area.

16. The bottom chassis of claim 15, wherein a width of the stress releasing area is greater than a width of the flange.

17. The bottom chassis of claim 15, wherein the cover portion is connected to the first area at a corner of the stress releasing area.

18. The bottom chassis of claim 14, wherein the stress releasing member is disposed between the flange and the at least one lateral wall.

19. The bottom chassis of claim 18, wherein the stress releasing member comprises:
a first bent portion extending from a top of the at least one lateral wall and bent in a direction opposite to a direction in which the at least one lateral wall is bent; and
a second bent portion extending from the first bent portion and bent in a direction opposite to a direction in which the first bent portion is bent, the second bent portion being connected with the flange.
